(19) United States
(12) Patent Application Publication
(10) Pub. No.: US 2021/0121957 A1
(43) Pub. Date: Apr. 29, 2021

(54) METHOD FOR PRODUCING METAL SHAPED ARTICLE HAVING POROUS STRUCTURE

(71) Applicant: SEIKO EPSON CORPORATION, Tokyo (JP)

(72) Inventor: Eiji OKAMOTO, MATSUMOTO-SHI (JP)

(21) Appl. No.: 17/080,283

(22) Filed: Oct. 26, 2020

(30) Foreign Application Priority Data
Oct. 25, 2019 (JP) 2019-194046

(51) Int. Cl. B22F 3/11

(52) U.S. Cl. CPC B22F 3/1121

(57) ABSTRACT

A method for producing a metal shaped article having a porous structure includes a shaping step of shaping a shaped article including a plurality of columns that contain a resin material and that extend from a substrate, and a sintering target material by repeatedly performing a resin material supply step of supplying a liquid containing the resin material to a plurality of places of the substrate at intervals in two directions crossing each other, a curing step of curing the liquid, and a sintering target material supply step of supplying the sintering target material to the substrate, a removal step of removing the substrate, a degreasing step of degreasing the columns, and a sintering step of sintering the sintering target material.

The present application is based on, and claims priority from JP Application Serial Number 2019-194046, filed on Oct. 25, 2019, the disclosure of which is hereby incorporated by reference herein in its entirety.

### BACKGROUND

### 1. Technical Field

The present disclosure relates to a method for producing a metal shaped article having a porous structure.

### 2. Related Art

Heretofore, there have been various metal shaped articles having a porous structure, that is, metal shaped articles having a porous structure including through-holes penetrating in the thickness direction. As a method for producing such a metal shaped article, a production method such as a sintering method, a dissolved gas casting method, or a processing method using a pulse laser or the like is known. For example, JP-A-2000-239760 (Patent Document 1) discloses, as the dissolved gas casting method, a method for producing a shaped article made of a metal having a porous structure by injecting a gas and also supplying a molten metal to a stock chamber and controlling a gas pressure.

However, in the method for producing a metal shaped article having a porous structure disclosed in Patent Document 1, it is necessary to increase the gas pressure for forming narrow empty holes, however, it is necessary to decrease the gas pressure for achieving a high porosity, and therefore, it is difficult to produce a metal shaped article having a porous structure with minute empty holes at high density. In this manner, in the method for producing a metal shaped article having a porous structure of the related art, a metal shaped article including through-holes penetrating in the thickness direction at high density could not be easily produced.

### SUMMARY

A method for producing a metal shaped article having a porous structure according to the present disclosure includes a shaping step of shaping a shaped article including a plurality of columns that contain a resin material and that extend from a substrate, and a sintering target material (a material to be sintered) by repeatedly performing a resin material supply step of supplying a liquid containing the resin material to a plurality of places of the substrate at intervals in two directions crossing each other, a curing step of curing the liquid, and a sintering target material supply step of supplying the sintering target material to the substrate, a removal step of removing the substrate, a degreasing step of degreasing the columns, and a sintering step of sintering the sintering target material.

### BRIEF DESCRIPTION OF THE DRAWINGS

FIG. 1 is a schematic configuration view of one embodiment of a production apparatus for a metal shaped article having a porous structure capable of performing some steps of a method for producing a metal shaped article having a porous structure according to the present disclosure.

FIG. 2 is a schematic view showing a part of the production apparatus for a metal shaped article having a porous structure in FIG. 1 during formation of columns.

FIG. 3 is a flowchart of a method for producing a metal shaped article having a porous structure according to one embodiment of the present disclosure.

FIG. 4 is a schematic cross-sectional view for illustrating the method for producing a metal shaped article having a porous structure according to one embodiment of the present disclosure.

FIG. 5 is a schematic cross-sectional view showing a loop heat pipe-type heat transfer device including a metal shaped article having a porous structure formed by performing the method for producing a metal shaped article having a porous structure according to one embodiment of the present disclosure.

### DESCRIPTION OF EXEMPLARY EMBODIMENTS

First, the present disclosure will be schematically described.

A method for producing a metal shaped article having a porous structure according to a first aspect of the present disclosure for solving the above problem includes a shaping step of shaping a shaped article including a plurality of columns that contain a resin material and that extend from a substrate, and a sintering target material by repeatedly performing a resin material supply step of supplying a liquid containing the resin material to a plurality of places of the substrate at intervals in two directions crossing each other, a curing step of curing the liquid, and a sintering target material supply step of supplying the sintering target material to the substrate, a removal step of removing the substrate, a degreasing step of degreasing the columns, and a sintering step of sintering the sintering target material.

According to this aspect, a shaped article in which a plurality of columns extend in the thickness direction can be easily formed by repeatedly performing the formation of the columns by supplying a liquid containing a resin material to a plurality of places of a substrate at intervals in two directions crossing each other and curing the liquid, and the supply of a sintering target material to the substrate, and a metal shaped article having a porous structure including through-holes penetrating in the thickness direction corresponding to the positions where the columns are formed can be easily produced by degreasing and sintering the shaped article. Then, by forming the columns at high density using, for example, an inkjet method or the like, the metal shaped article having a porous structure including through-holes at high density can be formed.

In a method for producing a metal shaped article having a porous structure according to a second aspect of the present disclosure, in the first aspect, in the shaping step, a binder supply step of supplying a liquid containing a binder to the sintering target material is performed after the sintering target material supply step.

According to this aspect, by supplying a liquid containing a binder to the sintering target material supplied to the substrate, a shaped article in which the sintering target material is bound can be formed, and the handling of the shaped article before sintering can be facilitated.

In a method for producing a metal shaped article having a porous structure according to a third aspect of the present disclosure, in the second aspect, the binder is the liquid to be supplied in the resin material supply step to the substrate.

According to this aspect, the binder and the liquid to be supplied in the resin material supply step can be commonized, and therefore, a device configuration for performing the method for producing a metal shaped article having a porous structure according to the present disclosure can be simplified.

In a method for producing a metal shaped article having a porous structure according to a fourth aspect of the present disclosure, in any one of the first to third aspects, in the resin material supply step, the liquid is ejected and supplied as a liquid droplet from a head.

According to this aspect, by adopting an inkjet method in which the liquid is ejected and supplied as a liquid droplet from a head, the columns can be easily and densely formed.

In a method for producing a metal shaped article having a porous structure according to a fifth aspect of the present disclosure, in any one of the first to fourth aspects, the sintering target material is in a paste form by containing a solvent, and a drying step of drying the solvent in the sintering target material is included after the sintering target material supply step.

According to this aspect, the sintering target material can be easily introduced to the substrate using the sintering target material in a paste form containing a solvent, and a structure of the sintering target material in a temporarily fixed state can be easily formed by drying the solvent in the sintering target material.

In a method for producing a metal shaped article having a porous structure according to a sixth aspect of the present disclosure, in any one of the first to fifth aspects, the shaping step includes a vibration step of vibrating the sintering target material supplied to the substrate by performing the sintering target material supply step before performing the resin material supply step.

The density of the sintering target material sometimes becomes low by merely supplying the sintering target material to the substrate, however, according to this aspect, by vibrating the sintering target material supplied to the substrate, the sintering target material can be densely filled, and the rigidity of the metal shaped article can be increased.

In a method for producing a metal shaped article having a porous structure according to a seventh aspect of the present disclosure, in the sixth aspect, in a period between the sintering target material supply step and the vibration step, the columns do not protrude from the sintering target material, and in a period after performing the vibration step, the columns protrude from the sintering target material.

According to this aspect, the columns before the vibration step do not protrude from the sintering target material, and therefore, collision of the columns with a member for supplying the sintering target material or the like involved in the supply of the columns can be suppressed. In addition, the columns after the vibration step protrude from the sintering target material, and therefore, the liquid containing a resin material can be supplied onto the columns formed at the substrate, so that the columns can be prevented from being discontinuously formed due to the sintering target material remaining on the columns.

In a method for producing a metal shaped article having a porous structure according to an eighth aspect of the present disclosure, in any one of the first to fifth aspects, the sintering target material contains a magnetic powder, and a magnetic field attraction step of generating a magnetic field where the magnetic powder is attracted to the substrate is included during the sintering target material supply step or after the sintering target material supply step.

According to this aspect, by attracting the sintering target material containing a magnetic powder to the substrate by the generated magnetic field, a gap can be prevented from occurring in the shaped article after supplying the sintering target material.

In a method for producing a metal shaped article having a porous structure according to a ninth aspect of the present disclosure, in any one of the first to fifth aspects, a compression step of pressurizing the sintering target material toward the substrate is included during the sintering target material supply step or after the sintering target material supply step.

According to this aspect, by pressurizing the sintering target material toward the substrate, the sintering target material can be supplied while suppressing occurrence of a gap.

In a method for producing a metal shaped article having a porous structure according to a tenth aspect of the present disclosure, in any one of the first to ninth aspects, a liquid repellent film is formed at the substrate, and in the resin material supply step, the liquid is supplied onto the liquid repellent film.

According to this aspect, by forming a liquid repellent film at the substrate, the columns to be formed on the substrate can be formed narrow, and the columns can be easily densified.

In a method for producing a metal shaped article having a porous structure according to an eleventh aspect of the present disclosure, in the tenth aspect, the liquid repellent film is made of a resin, and in the degreasing step, not only the columns, but also the liquid repellent film is degreased.

According to this aspect, the columns and the liquid repellent film can be simultaneously degreased, and therefore, a burden involved in degreasing can be reduced.

In a method for producing a metal shaped article having a porous structure according to a twelfth aspect of the present disclosure, in any one of the first to eleventh aspects, in the sintering target material supply step, the sintering target material is supplied so that a thickness of the sintering target material from the substrate is equal to or less than a length of the column from the substrate.

According to this aspect, the sintering target material is supplied so that a thickness of the sintering target material from the substrate is equal to or less than a length of the column from the substrate, and therefore, the portions where the columns are formed can be made through-holes penetrating in the thickness direction even if a post-treatment or the like is simplified or omitted.

In a method for producing a metal shaped article having a porous structure according to a thirteenth aspect of the present disclosure, in any one of the first to eleventh aspects, in the sintering target material supply step, the sintering target material is supplied so that a thickness of the sintering target material from the substrate exceeds a length of the column from the substrate, and a grinding step of grinding a face of the sintering target material at an opposite side to a face thereof where the substrate is disposed until the columns are exposed is included before the degreasing step.

According to this aspect, by grinding a face of the sintering target material at an opposite side to a face thereof where the substrate is disposed until the columns are exposed, the portions where the columns are formed can be made through-holes reliably penetrating in the thickness direction. Further, by performing grinding before degreasing, a sintering target material piece generated by grinding in the through-holes can be prevented from being mixed in the through-holes.

In a method for producing a metal shaped article having a porous structure according to a fourteenth aspect of the present disclosure, in any one of the first to thirteenth aspects, in the shaping step, an operation, in which the resin material supply step and the curing step are repeated a plurality of times, and thereafter the sintering target material supply step is performed, is repeatedly performed.

According to this aspect, the sintering target material is supplied after forming the columns having a predetermined length by repeating supply and curing of the resin material a plurality of times, and therefore, the metal shaped article can be efficiently produced.

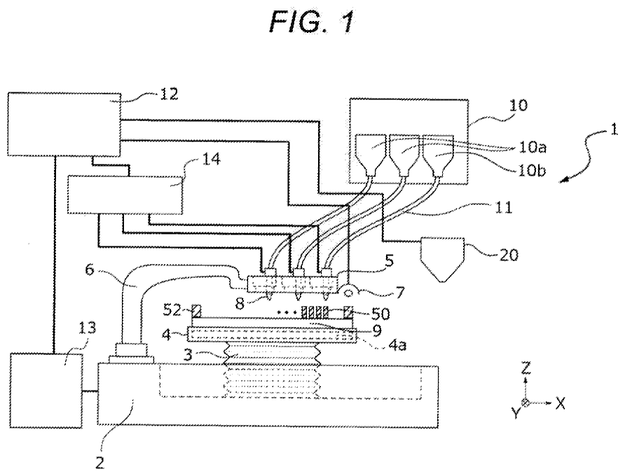

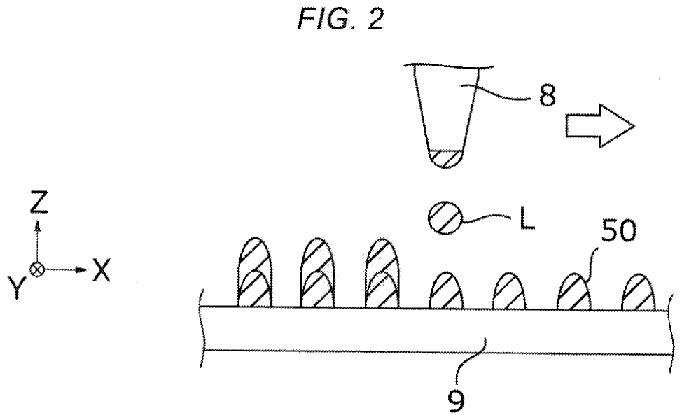

Hereinafter, embodiments according to the present disclosure will be specifically described with reference to the drawings. First, one embodiment of a production apparatus 1 for a metal shaped article having a porous structure capable of performing some steps of the method for producing a metal shaped article having a porous structure according to the present disclosure will be described with reference to FIGS. 1 and 2. Note that the “three-dimensional shaping” as used herein refers to forming a so-called three-dimensional shaped article, and also includes, for example, forming a shape having a thickness even if it is a flat shape or a so-called two-dimensional shape.

As shown in FIG. 1, the production apparatus 1 for a metal shaped article having a porous structure of this embodiment includes a base stand 2 and a stage 4 provided so as to be movable in the X-axis direction, Y-axis direction, and Z-axis direction shown in the drawing, or drivable in the rotational direction about the Z-axis by a driving device 3 as a driving unit included in the base stand 2. Then, the apparatus includes a head base support portion 6, one end portion of which is fixed to the base stand 2, and the other end portion of which is fixed to a head base 5 for holding a plurality of heads 8, each of which ejects a liquid L (see FIG. 2) containing a resin material.

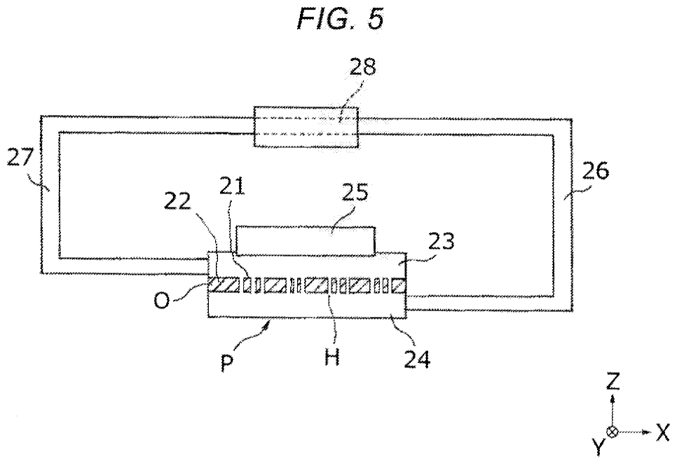

Here, the liquid L containing a resin material to be used in the production apparatus 1 for a metal shaped article having a porous structure of this embodiment contains a photocurable resin that is cured by irradiation with light. The production apparatus 1 for a metal shaped article having a porous structure includes a light irradiation portion 7 that irradiates light for curing the liquid L. On the stage 4, a substrate 9 at which a metal shaped article O having a porous structure (see FIG. 5) is formed is placed. The liquid L is ejected to the substrate 9.

On the stage 4, the substrate 9 at which the metal shaped article O having a porous structure is formed is placed. The liquid L is ejected to the substrate 9. The substrate 9 of this embodiment is a substrate made of a nonmagnetic metal that is tough and is easily produced. However, as the substrate 9, for example, a substrate made of a ceramic can be preferably used. By using the substrate 9 made of a ceramic, high heat resistance can be obtained, and further, the reactivity with the constituent material of the metal shaped article O having a porous structure to be subjected to degreasing, sintering, or the like is also low, and thus, deterioration of the metal shaped article O having a porous structure can be prevented. In FIGS. 1 and 2, a state where columns 50 are formed at the substrate 9 by repeating ejection and curing of the liquid L is shown. In detail, in FIG. 2, a state where the columns 50 extending in the Z-axis direction are formed by ejecting the liquid L at the same positions viewed from the Z-axis direction while relatively moving the head 8 in the direction of the open arrow with respect to the stage 4 is shown. Note that in FIG. 2, a state during the formation of the second stage in the Z-axis direction in the column 50 is shown, however, the column 50 may be constituted by any number of stages. The production apparatus 1 for a metal shaped article having a porous structure of this embodiment is configured to form a stacked body of the column 50 by stacking a plurality of layers in the Z-axis direction by regarding one stage in the Z-axis direction as one layer.

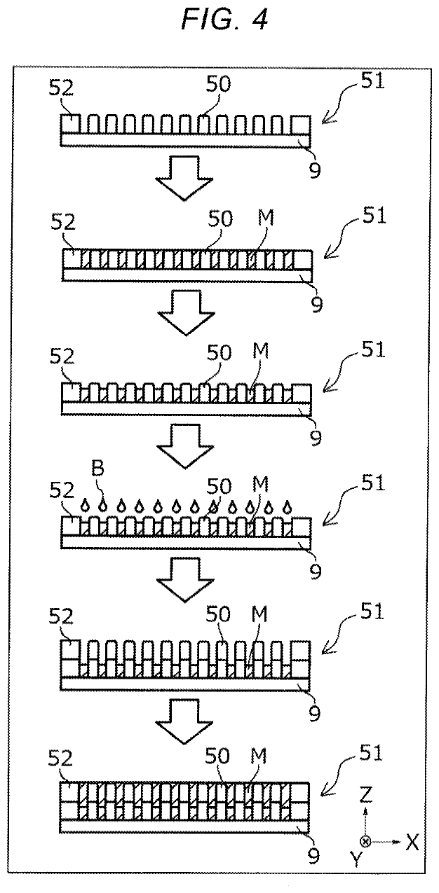

As shown in FIG. 1, each head 8 held by the head base 5 is coupled, via a supply tube 11, to a liquid supply unit 10 including a liquid storage portion 10a storing the liquid L made to correspond to each head 8. In this manner, by including the liquid storage portion 10a corresponding to each head 8, a plurality of different types of liquids L can be supplied from the head base 5. By using the head base 5 having such a configuration, a shaped article 51 (see FIG. 4) having a plurality of columns 50 extending from the substrate 9 can be formed. Note that it becomes possible to form the columns 50 at high density in a short time by arranging a plurality of nozzles in the head 8 and supplying the liquid L from the plurality of nozzles.

Here, as shown in FIG. 1, for the head base 5 of this embodiment, the liquid supply unit 10 includes a liquid storage portion 10b in addition to the liquid storage portion 10a. Some heads 8 in the head base 5 are coupled to the liquid storage portion 10b via a supply tube 11. The liquid storage portion 10b stores a binder B (see FIG. 4) for binding metal particles of a sintering target material M (see FIG. 4) to serve as the constituent material of the metal shaped article O having a porous structure, and is configured to be able to eject the binder B from the head 8 coupled to the liquid storage portion 10b.

As shown in FIG. 1, the production apparatus 1 for a metal shaped article having a porous structure of this embodiment includes a sintering target material supply portion 20 that supplies the sintering target material M to the substrate 9 at which the columns 50 are provided. The sintering target material supply portion 20 of this embodiment is a hopper capable of storing and discharging the sintering target material M, but there is no particular limitation on the configuration of the sintering target material supply portion 20. The shaped article 51 to which the sintering target material M is supplied is subjected to degreasing and sintering using a heating device or the like that is an external device. Here, it is preferred to form an outer wall portion 52 with the liquid L along the outline portion of the substrate 9 as the columns 50 are formed so that the sintering target material M does not fall out of the substrate 9 when the sintering target material M is supplied to the substrate 9. Further, a magnet 4a is enclosed in the stage 4, so that the filling accuracy of the sintering target material M when a magnetic substance is used as the sintering target material M is enhanced.

The production apparatus 1 for a metal shaped article having a porous structure is provided with a control unit 12 that controls the respective constituent portions such as the stage 4, the head base 5, the head 8, the light irradiation portion 7, and the sintering target material supply portion 20 based on the data for shaping the metal shaped article O having a porous structure output from, for example, a data output device such as a personal computer (not shown). By the control of the control unit 12, the stage 4, the head base 5, the head 8, the light irradiation portion 7, the sintering target material supply portion 20, and the like are driven in conjunction with one another. The control unit 12 of this embodiment includes one or more processors, a storage device, and an interface for performing signal input/output to/from the outside. Then, the control unit 12 of this embodiment causes the respective constituent portions to execute an operation of producing the metal shaped article O having a porous structure by execution of a program or a command read on the storage device by the processor. The control unit 12 may be constituted, not by a computer, but by combining a plurality of circuits.

Based on the control signal from the control unit 12, a signal for controlling the start and stop of the movement, moving direction, moving amount, moving speed, or the like of the stage 4 is generated in a stage controller 13. The signal is transmitted to the driving device 3 included in the base stand 2, and the stage 4 moves in the X-axis direction, Y-axis direction, and Z-axis direction. In the head 8, based on the control signal from the control unit 12, an ejection signal for the liquid L is generated, and based on the generated ejection signal, the head controller 14 controls the driving of each head 8, thereby ejecting the liquid L. The binder B is also ejected by the control of the control unit 12 in the same manner as the liquid L.

Next, the composition of a preferred liquid L will be described. The liquid L contains a resin material. As the resin material, for example, as a photocurable resin, an acrylic resin, a methacrylic resin, an epoxy resin, or a urethane resin, as a thermoplastic resin, an ABS resin, a PC resin, or a PP resin, as a thermosetting resin, an epoxy resin or the like can be preferably used. Further, the liquid L may contain a solvent, and as the solvent, diethylene glycol monobutyl ether acetate (CAS No: 124-17-4), or the like can be preferably used. Note that the production apparatus 1 for a metal shaped article of this embodiment is configured to be able to also eject the binder B, but may use the liquid L as the binder B. That is, the same resin material as the liquid L can be preferably used also as the binder B.

Next, a preferred sintering target material M will be described. As the sintering target material M, for example, magnesium (Mg), iron (Fe), cobalt (Co), chromium (Cr), aluminum (Al), titanium (Ti), copper (Cu), nickel (Ni), or a mixture such as an alloy containing one or more of these metals (a maraging steel, a stainless steel, cobalt chromium molybdenum, a titanium alloy, a nickel alloy, an aluminum alloy, a cobalt alloy, or a cobalt-chromium alloy), or a ceramic such as silicon dioxide, titanium dioxide, aluminum oxide, or zirconium oxide can be preferably used. Further, the material may be in a paste form, a slurry form, or the like containing a solvent such as propylene glycol, water, or butanediol or a binder resin such as polyvinyl alcohol (PVA), polyvinylpyrrolidone (PVP), or a starch (amylose or amylopectin) in addition thereto.

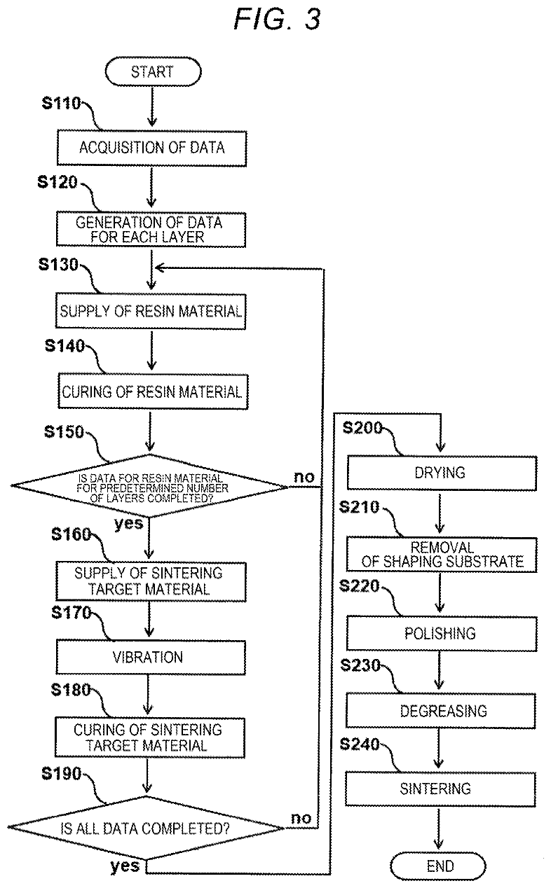

Next, one example of the method for producing a metal shaped article having a porous structure to be performed using the production apparatus 1 for a metal shaped article having a porous structure will be described with reference to the flowchart of FIG. 3 and also FIGS. 4 and 5.

As shown in FIG. 3, in the method for producing a metal shaped article having a porous structure of this embodiment, first, in Step S110, data of the metal shaped article O having a porous structure to be produced is acquired. In detail, for example, from an application program or the like executed in a personal computer, data representing the shape of the metal shaped article O having a porous structure are acquired.

Subsequently, in Step S120, by the control of the control unit 12, data for each layer are generated. In detail, the data representing the shape of the metal shaped article O having a porous structure are sliced according to the shaping resolution in the Z-axis direction, whereby cross-sectional data that are bit map data are generated for each cross section.

Subsequently, in a resin material supply step of Step S130, by the control of the control unit 12, the liquid L containing a resin material is ejected from the head 8 based on the cross-sectional data generated in Step S120, whereby the columns 50 based on the cross-sectional data are formed at the substrate 9. Here, the positions where the liquid L is ejected to the substrate 9, that is, the positions where the columns 50 are formed are positions spaced at intervals in both the X-axis direction and the Y-axis direction, that is, staggered arrangement. When expressed in another way, in this Step S130, the liquid L containing a resin material is supplied to a plurality of places of the substrate 9 at intervals in two directions crossing each other. In this Step S130, it is preferred to also form the outer wall portion 52 together with the columns 50 at the substrate 9.

Subsequently, in a resin material curing step of Step S140, by the control of the control unit 12, the liquid L is cured by irradiating light such as ultraviolet light from the light irradiation portion 7. In the method for producing a metal shaped article having a porous structure of this embodiment, the liquid L containing a photocurable resin as the resin material is used, and therefore, a light irradiation step of irradiating light from the light irradiation portion 7 is adopted, however, depending on the resin material to be used, a step different from the light irradiation step can be adopted as the curing step. For example, when the liquid L containing a thermosetting resin as the resin material is used, a heating step may be adopted as the curing step. Further, when the liquid L containing a thermoplastic resin as the resin material is used, a cooling step may be adopted as the curing step.

Then, in Step S150, by the control of the control unit 12, Step S130 and Step S140 are repeated for a predetermined number of layers. For example, by repeating shaping of the columns 50 to be formed so that the thickness for one layer is 10 μm for 5 layers, the columns 50 having a thickness of 50 μm are formed. That is, in the method for producing a metal shaped article having a porous structure of this embodiment, a mold of the shaped article 51 including a plurality of columns 50 extending from the substrate 9 is formed by the resin material supply step of Step S130 and the resin material curing step of Step S140. The top view in FIG. 4 shows a mold for five layers, which is completed by repeating Step S130 to Step S150 five times, and in which the plurality of columns 50 are formed at the substrate 9, and also the outer wall portion 52 is formed along the outline portion of the substrate 9. As the columns 50, for example, structures having an outer diameter of 30 μm or more and 50 μm or less can be formed at intervals of 30 μm or more and 70 μm or less between the centers of the columns.

After the mold for a predetermined number of layers is formed by repeating Step S130 to Step S150, in a sintering target material supply step of Step S160, by the control of the control unit 12, the sintering target material M is supplied to the mold from the sintering target material supply portion 20. The second view from the top in FIG. 4 shows a state where this Step S160 is performed, and the sintering target material M is supplied to the mold.

Then, after performing the sintering target material supply step of Step S160, in a vibration step of Step S170, the mold is vibrated by ultrasonic vibration or the like together with the substrate 9. The third view from the top in FIG. 4 shows a state where this Step S170 is performed, and the mold is vibrated and the sintering target material M is densely filled.

Subsequently, in a sintering target material curing step of Step S180, by the control of the control unit 12, the binder B is ejected to the sintering target material M from the head 8 and the sintering target material M is cured by the binder B. The fourth view from the top in FIG. 4 shows a state where this Step S180 is performed, and the binder B is ejected to the sintering target material M from the head 8. In this embodiment, a step of curing the sintering target material M by ejecting the binder B from the head 8 is adopted in the sintering target material curing step, but the sintering target material curing step is not limited to such a step. Instead of adopting such a step, for example, a step of performing curing by ejecting the liquid L to the sintering target material M from the head 8, and thereafter, irradiating light from the light irradiation portion 7 may be adopted.

Then, the control unit 12 repeats the respective steps from Step S130 to Step S190 until the formation of the shaped article 51 based on the data for each layer generated in Step S120 is completed. Here, the fifth view from the top in FIG. 4 shows a state where Step S130 to Step S150 are further repeatedly performed for 5 layers from the state shown in the fourth view from the top in FIG. 4. Then, the bottom view in FIG. 4 shows a state where Step S160 and Step S170 are further performed thereafter from the state shown in the fifth view from the top in FIG. 4. By repeating the respective steps from Step S130 to Step S190, for example, the shaped article 51 having the columns 50 in which the aspect ratio that is the ratio of the diameter of the column 50 when viewed from the Z-axis direction and the length of the column 50 in the Z-axis direction is 10 or more can be formed.

Then, in a drying step of Step S200, the solvent contained in the sintering target material M or a volatile component of the binder B ejected to the sintering target material M is volatilized and dried. In this embodiment, the sintering target material M in a paste form containing a solvent is used and also the binder B is ejected to the sintering target material M, and therefore, this Step S200 is performed, however, when the sintering target material M in a paste form is not used or when the binder B is not ejected to the sintering target material M, this Step S200 can be omitted.

Subsequently, in a removal step of Step S210, the substrate 9 is removed. In this Step S210, the outer wall portion 52 is also removed along with the removal of the substrate 9. However, the outer wall portion 52 may not be removed in this Step S210 and may be degreased together with the columns 50 in a degreasing step of Step S230 described later.

Subsequently, in a grinding step of Step S220, an upper face portion of the structure of the metal shaped article O having a porous structure resulting from the removal of the substrate 9 and the outer wall portion 52 in Step S210 is ground. However, this Step S220 can also be omitted according to the supply state of the sintering target material M, or the like.

Then, in a degreasing step of Step S230, the columns 50 are degreased using, for example, a heating device (not shown) or the like, and in a sintering step of Step S240, sintering of the sintering target material M is performed by heating the structure of the metal shaped article O having a porous structure using the heating device or the like. Then, with the completion of Step S240, the method for producing a metal shaped article having a porous structure of this embodiment is completed. The removal step of Step S210 may be performed after the degreasing step of Step S230 or the like according to the type of the metal shaped article O having a porous structure to be produced or the like.

The metal shaped article O having a porous structure is shrunk by performing the sintering step of Step S240. By utilizing such shrinkage, the through-holes H (see FIG. 5) can be arranged at particularly high density. Here, the through-holes H are formed at the positions where the columns 50 have been formed as the columns 50 are degreased in the degreasing step of Step S230. When the outer wall portion 52 is not removed in the removal step of Step S210, the outer wall portion 52 is degreased together with the columns 50 in the degreasing step of Step S230.

FIG. 5 is a schematic cross-sectional view showing a loop heat pipe-type heat transfer device P including the metal shaped article O having a porous structure formed by performing the method for producing a metal shaped article having a porous structure of this embodiment. The loop heat pipe-type heat transfer device P shown in FIG. 5 is a device for cooling a heat source 25 such as a semiconductor chip. The loop heat pipe-type heat transfer device P shown in FIG. 5 includes a housing in which a bottom face is disposed so as to enable heat transfer with the heat source 25, a steam pipe 27, a liquid pipe 26, and a condenser 28. In the housing, the porous metal shaped article O having a porous structure is placed, and an evaporation chamber 23 and a liquid chamber 24 communicate with each other through the through-holes H. At that time, the bottom face of the loop heat pipe-type heat transfer device P forms a part of the evaporation chamber 23. The steam pipe 27 is coupled to the evaporation chamber 23 and the condenser 28, and the liquid pipe 26 is coupled to the liquid chamber 24 and the condenser 28. It includes a low-density portion 21 that is the metal shaped article O having a porous structure with a plurality of through-holes H produced as described above and a plurality of columnar high-density portions 22. The low-density portion 21 and the high-density portions 22 are configured to be coupled to each other. It may be configured to have the through-holes H entirely.

Cooling water supplied to the liquid chamber 24 from the liquid pipe 26 is introduced into the evaporation chamber 23 through the through-holes H by a capillary phenomenon. The cooling water introduced into the evaporation chamber 23 is converted to steam in the evaporation chamber 23 by the heat of the heat source 25. When the cooling water is converted to steam in the evaporation chamber 23, heat is taken from the heat source 25 due to vaporization heat. In this manner, the loop heat pipe-type heat transfer device P shown in FIG. 5 cools the heat source 25. The vaporized steam flows in the condenser 28 through the steam pipe 27 and is liquified again by being cooled in the condenser 28. As the through-holes H are provided at higher density, the cooling water can more efficiently move through the through-holes H. In addition, as the through-holes H are more minute, the capillary phenomenon more efficiently occurs. Therefore, the metal shaped article O having a porous structure including the through-holes H with a narrow diameter at high density is desired.

As described above, the method for producing a metal shaped article having a porous structure of this embodiment includes the shaping step of shaping the shaped article 51 having the plurality of columns 50 that contain a resin material and that extend from the substrate 9, and the sintering target material M by repeatedly performing the resin material supply step of Step S130 of supplying the liquid L containing the resin material to a plurality of places of the substrate 9 at intervals in two directions crossing each other, the resin material curing step of Step S140 of curing the liquid L, and the sintering target material supply step of Step S160 of supplying the sintering target material M to the substrate 9. The method further includes the removal step of Step S210 of removing the substrate 9, the degreasing step of Step S230 of degreasing the columns 50, and the sintering step of Step S240 of sintering the sintering target material M. By performing the method for producing a metal shaped article having a porous structure of this embodiment, the shaped article 51 in which the plurality of columns 50 extend in the thickness direction that is a direction along the Z-axis direction can be easily formed by repeatedly performing the formation of the columns 50 by supplying the liquid L containing the resin material to a plurality of places of the substrate 9 at intervals in two directions crossing each other and curing the liquid L, and the supply of the sintering target material M to the substrate 9. Then, the metal shaped article O having a porous structure including the through-holes H penetrating in the thickness direction corresponding to the positions where the columns 50 are formed can be easily produced by degreasing and sintering the shaped article 51.

Here, the head 8 in the production apparatus 1 for a metal shaped article having a porous structure is a head employing an inkjet method for ejecting the liquid L as a liquid droplet. That is, in the method for producing a metal shaped article having a porous structure of this embodiment, the liquid L is ejected and supplied as a liquid droplet from the head 8 in the resin material supply step of Step S130. In this manner, by adopting an inkjet method for ejecting and supplying the liquid L as a liquid droplet from the head 8, the columns 50 can be easily and densely formed.

Here, the resin material supply step of Step S130 may be performed using, for example, a microneedle or the like for ejecting the liquid L in a liquid columnar shape without using the head employing an inkjet method for ejecting the liquid L as a liquid droplet. However, when the columns 50 are formed using a microneedle or the like, the diameters of the columns 50 when viewed from the Z-axis direction hardly become uniform, and further, it is difficult to form the columns 50 at high density as compared with the case where the head employing an inkjet method is used, and therefore, it is particularly preferred to use the head employing an inkjet method.

The sintering target material M to be used in the method for producing a metal shaped article having a porous structure of this embodiment is in a paste form by containing a solvent, and the drying step of Step S200 of drying the solvent in the sintering target material M is included after the sintering target material supply step of Step S160. That is, by performing the method for producing a metal shaped article having a porous structure of this embodiment, the sintering target material M can be easily introduced to the substrate 9 using the sintering target material M in a paste form containing a solvent, and the structure of the sintering target material M in a temporarily fixed state before sintering can be easily formed by drying the solvent in the sintering target material M.

In the method for producing a metal shaped article of this embodiment, in the shaping step to be performed by repeating the steps from the resin material supply step of Step S130 to the sintering target material curing step of Step S180, an operation, in which the resin material supply step of Step S130 and the resin material curing step of Step S140 are repeated a plurality of times, and thereafter the sintering target material supply step of Step S160 is performed, is repeatedly performed. That is, in the method for producing a metal shaped article of this embodiment, the sintering target material M is supplied after forming the columns 50 having a predetermined length by repeating supply and curing of the resin material a plurality of times, and therefore, the metal shaped article O can be efficiently produced.

Here, in the shaping step, after the sintering target material supply step of Step S160, the sintering target material curing step of Step S180 is performed as the binder supply step of supplying the binder B as a liquid containing a binder to the sintering target material M. By supplying a liquid containing a binder to the sintering target material M supplied to the substrate 9, a shaped article in which the sintering target material M is bound can be formed, and the handling of the shaped article before sintering can be facilitated.

In the sintering target material curing step of Step S180, instead of supplying the binder B as the binder, the liquid L to be supplied in the resin material supply step of Step S130 may be supplied. By using the liquid L as the binder, the binder and the liquid to be supplied in the resin material supply step of Step S130 can be commonized, and therefore, a device configuration for performing the method for producing a metal shaped article having a porous structure can be simplified.

Further, as described above, the shaping step includes the vibration step of Step S170 of vibrating the sintering target material M supplied to the substrate 9 by performing the sintering target material supply step of Step S160 before performing the resin material supply step of Step S130. The density of the sintering target material M sometimes becomes low by merely supplying the sintering target material M to the substrate 9, however, as in this embodiment, by vibrating the sintering target material M supplied to the substrate 9, the sintering target material M can be densely filled, and the rigidity of the metal shaped article O can be increased.

Here, in the method for producing a metal shaped article having a porous structure of this embodiment, as shown in the second view and the third view from the top in FIG. 4, in the sintering target material supply step of Step S160, the sintering target material M is supplied so that the columns 50 before performing the vibration step of Step S170 come in a state where the structures do not protrude from the sintering target material M, and the columns 50 after performing the vibration step of Step S170 come in a state where the structures protrude from the sintering target material M. By bringing the columns 50 before performing vibration into a state where the structures do not protrude from the sintering target material M, collision of the columns 50 with the sintering target material supply portion 20 that is a member for supplying the sintering target material M or the like involved in the supply of the columns 50 can be suppressed. In addition, by bringing the columns 50 after performing vibration into a state where the structures protrude from the sintering target material M, the liquid L containing a resin material can be supplied onto the columns 50 formed at the substrate 9, so that the columns 50 can be prevented from being discontinuously formed due to the sintering target material M remaining on the columns 50.

Further, as described above, in the production apparatus 1 for a metal shaped article having a porous structure of this embodiment, the magnet 4a is included in the stage 4. Then, in the method for producing a metal shaped article having a porous structure of this embodiment, the sintering target material M containing a magnetic powder of, for example, stainless steel (SUS) or the like can be used. That is, the method for producing a metal shaped article having a porous structure of this embodiment can be expressed such that the sintering target material M contains a magnetic powder, and a magnetic field attraction step of generating a magnetic field where the magnetic powder in the sintering target material M is attracted to the substrate 9 is included during the sintering target material supply step of Step S160 or after the sintering target material supply step of Step S160. In this manner, by generating a magnetic field so as to attract the sintering target material M containing a magnetic powder to the substrate 9 during the sintering target material supply step of Step S160 or after the sintering target material supply step of Step S160, the sintering target material can be supplied to the mold of the shaped article 51 while suppressing occurrence of a gap. The magnet 4a of this embodiment is a thin cylindrical magnet, however, the shape of the magnet is not particularly limited as long as the shape allows the magnetic lines of force toward the substrate 9 to be generated, and for example, a ring-shaped magnet surrounding the stage 4 from the circumference thereof, or the like can also be used.

Here, a preferred magnetic field attraction step will be described in detail. For example, a preferred magnetic field attraction step can be performed using the sintering target material M containing a SUS powder having an average particle diameter of 4 μm, PVA as a binder, and propylene glycol as a solvent, and also using a cylindrical or ring-shaped ferrite magnet or neodymium magnet configured to make the magnetic flux density on the stage 4 substantially uniform. As the stage 4 or the substrate 9, non-magnetic austenitic stainless steel, a ceramic, or the like can be preferably used.

A compression step of pressurizing the sintering target material M toward the substrate 9 may also be performed during the sintering target material supply step of Step S160 or after the sintering target material supply step of Step S160 in place of the magnetic field attraction step. This is because also by pressurizing the sintering target material M toward the substrate 9, the sintering target material M can be supplied to the mold of the shaped article 51 while suppressing occurrence of a gap.

Here, it is preferred to use a substrate having a liquid repellent film formed at the surface thereof as the substrate 9. This is because, in the resin material supply step of Step S130, by supplying the liquid L onto the liquid repellent film, the liquid L can be prevented from spreading too wide on the substrate 9, and the columns 50 to be formed on the substrate 9 can be formed narrow, and thus, the columns 50 can be easily densified. By forming the liquid repellent film at the surface of the substrate 9, a decrease in adhesion strength between the substrate 9 and the column 50 can also be suppressed. Therefore, it becomes easy to carry the structure of the metal shaped article O having a porous structure during production.

In particular, it is preferred to use the substrate 9 at which the liquid repellent film made of a resin is formed. This is because, in the degreasing step of Step S230, not only the columns 50, but also the liquid repellent film can be simultaneously degreased, and therefore, a burden involved in degreasing can be reduced.

In the method for producing a metal shaped article having a porous structure of this embodiment, in the sintering target material supply step of Step S160, the sintering target material M is supplied to the mold of the shaped article 51 so that the thickness of the sintering target material M from the substrate 9 exceeds the length of the column 50 from the substrate 9. However, by performing the vibration step of Step S170, the columns 50 come in a state where the structures are exposed at a face of the sintering target material M at an opposite side to a face thereof where the substrate 9 is disposed. Therefore, the shaped article 51 to be formed after completion of the shaping step is configured such that the columns 50 penetrate the sintering target material M.

When expressed in another way, in the sintering target material supply step of Step S160, the sintering target material M is supplied to the mold of the shaped article 51 so that the thickness of the sintering target material M from the substrate 9 is equal to or less than the length of the column 50 from the substrate 9. By doing this, a post-treatment such as the grinding step of Step S220 can be omitted. This is because by supplying the sintering target material M to the mold of the shaped article 51 so that the thickness of the sintering target material M from the substrate 9 is equal to or less than the length of the column 50 from the substrate 9, even if such a post-treatment or the like is simplified or omitted, the portions where the columns 50 are formed can be made the through-holes H penetrating in the thickness direction. Although it is obvious from the above description, the reference time for determining that “the thickness of the sintering target material M from the substrate 9 is equal to or less than the length of the column 50 from the substrate 9” is the end of the shaping step.

However, in the sintering target material supply step of Step S160 at the final stage of repetition in the shaping step, the sintering target material M may be supplied so that the thickness of the sintering target material M from the substrate 9 exceeds the length of the column 50 from the substrate 9 even after performing the vibration step of Step S170. In that case, before the degreasing step of Step S230, in the grinding step of Step S220, a face of the sintering target material M at an opposite side to a face thereof where the substrate 9 is disposed is ground until the columns 50 are exposed. By doing this, the portions where the columns 50 are formed can be formed into the through-holes H reliably penetrating in the thickness direction. By performing grinding before degreasing, a sintering target material piece generated by grinding in the through-holes H can be prevented from being mixed in the through-holes H. Here, instead of performing the grinding step of Step S220, a cutting step of cutting a face of the sintering target material M at an opposite side to a face thereof where the substrate 9 is disposed along the X-axis direction and the Y-axis direction may be performed. The cutting step can be performed by, for example, wire electric discharge machining or the like.

The present disclosure is not limited to the above-mentioned embodiments, but can be realized in various configurations without departing from the gist of the present disclosure. For example, the technical features in the embodiments corresponding to the technical features in the respective aspects described in “SUMMARY” of the present disclosure may be appropriately replaced or combined in order to solve part or all of the problems described above or achieve part or all of the advantageous effects described above. Further, the technical features may be appropriately deleted unless they are described as essential features in the specification.

What is claimed is:

1. A method for producing a metal shaped article having a porous structure, comprising:
a shaping step of shaping a shaped article including a plurality of columns that contain a resin material and that extend from a substrate, and a sintering target material by repeatedly performing a resin material supply step of supplying a liquid containing the resin material to a plurality of places of the substrate at intervals in two directions crossing each other, a curing step of curing the liquid, and a sintering target material supply step of supplying the sintering target material to the substrate;
a removal step of removing the substrate;
a degreasing step of degreasing the columns; and
a sintering step of sintering the sintering target material.

2. The method for producing a metal shaped article having a porous structure according to claim 1, wherein
in the shaping step, a binder supply step of supplying a liquid containing a binder to the sintering target material is performed after the sintering target material supply step.

3. The method for producing a metal shaped article having a porous structure according to claim 2, wherein
the binder is the liquid to be supplied in the resin material supply step to the substrate.

4. The method for producing a metal shaped article having a porous structure according to claim 1, wherein
in the resin material supply step, the liquid is ejected and supplied as a liquid droplet from a head.

5. The method for producing a metal shaped article having a porous structure according to claim 1, wherein
the sintering target material is in a paste form by containing a solvent, and
a drying step of drying the solvent in the sintering target material is included after the sintering target material supply step.

6. The method for producing a metal shaped article having a porous structure according to claim 1, wherein
the shaping step includes a vibration step of vibrating the sintering target material supplied to the substrate by performing the sintering target material supply step before performing the resin material supply step.

7. The method for producing a metal shaped article having a porous structure according to claim 6, wherein
in a period between the sintering target material supply step and the vibration step, the columns do not protrude from the sintering target material, and in a period after performing the vibration step, the columns protrude from the sintering target material.

8. The method for producing a metal shaped article having a porous structure according to claim 1, wherein
the sintering target material contains a magnetic powder, and
a magnetic field attraction step of generating a magnetic field where the magnetic powder is attracted to the substrate is included during the sintering target material supply step or after the sintering target material supply step.

9. The method for producing a metal shaped article having a porous structure according to claim 1, wherein
a compression step of pressurizing the sintering target material toward the substrate is included during the sintering target material supply step or after the sintering target material supply step.

10. The method for producing a metal shaped article having a porous structure according to claim 1, wherein
a liquid repellent film is formed at the substrate, and
in the resin material supply step, the liquid is supplied onto the liquid repellent film.

11. The method for producing a metal shaped article having a porous structure according to claim 10, wherein
the liquid repellent film is made of a resin, and
in the degreasing step, not only the columns, but also the liquid repellent film is degreased.

12. The method for producing a metal shaped article having a porous structure according to claim 1, wherein
in the sintering target material supply step, the sintering target material is supplied so that a thickness of the sintering target material from the substrate is equal to or less than a length of the column from the substrate.

13. The method for producing a metal shaped article having a porous structure according to claim 1, wherein
in the sintering target material supply step, the sintering target material is supplied so that a thickness of the sintering target material from the substrate exceeds a length of the column from the substrate, and
a grinding step of grinding a face of the sintering target material at an opposite side to a face thereof where the substrate is disposed until the columns are exposed is included before the degreasing step.

14. The method for producing a metal shaped article having a porous structure according to claim 1, wherein
in the shaping step, an operation, in which the resin material supply step and the curing step are repeated a plurality of times, and thereafter the sintering target material supply step is performed, is repeatedly performed.
